(19) United States
(12) Patent Application Publication
(10) Pub. No.: US 2015/0028848 A1
(43) Pub. Date: Jan. 29, 2015

(54) Wireless Monitoring of Power Draw from Individual Breakers Within a Circuit Breaker Panel

(71) Applicant: Bractlet, LLC, Houston, TX (US)

(72) Inventors: Matthew Lynch, Houston, TX (US); Brian Smith, Houston, TX (US); Alec Manfre, Houston, TX (US)

(21) Appl. No.: 14/341,537

(22) Filed: Jul. 25, 2014

Related U.S. Application Data
(60) Provisional application No. 61/858,169, filed on Jul. 25, 2013.

(51) Int. Cl. G01R 21/00

(52) U.S. Cl. CPC G01R 21/00
USPC 324/76.11

(57) ABSTRACT

Disclosed herein is hardware that can be fitted to a pre-existing circuit breaker panel to allow for the monitoring of power draws in the various circuit breaker branches, which hardware includes current transducers coupled to a wireless hub. The current transducers are coupled to the wires proceeding from each of the circuit breaker branches. The hub computes the power draws for each of the branches using the information provided by the CT as well as the AC input voltages provided to the panel. The hub reports these power draws to an Internet gateway, where the results can be viewed at a web server. The web server may also comprise an analysis module that reviews present and historical power draw data to provide useful power consumption information to a customer for example.

### CROSS REFERENCE TO RELATED APPLICATIONS

This application claims priority to U.S. Provisional Patent Application Ser. No. 61/858,169, filed Jul. 25, 2013, which is incorporated herein by reference in its entirety.

### FIELD OF THE INVENTION

The present invention relates to wireless monitoring of power draws from branch circuit breakers in a circuit breaker panel.

### BACKGROUND

FIG. 1 shows a circuit breaker panel 10 such as is typically found in a home, office building, or other site. The circuit breaker panel 10 includes a number of branch circuit breakers 20 that couple to various electrical loads. For example, in a home, a first branch breaker 20 might couple to a High Voltage Air Conditioning (HVAC) unit; a second might couple to all of the electrical outlets (i.e., wall plugs) in a particular room, such as the kitchen; a third might couple to the overhead lights on the first floor, etc.

Such branch circuit breakers 20 are designed to prevent an overcurrent condition from occurring in any of the branches it serves. For example, if the current being drawn by the HVAC unit coupled to the first branch circuit breaker exceeds the current limit for that breaker (e.g., 25 Amps), that breaker will “trip,” i.e., it will automatically switch to the “off” state to prevent current from flowing in that branch, which current might damage the HVAC unit or otherwise present a safety hazard. Once tripped, a user can flip the breaker 20 back to the “on” state to attempt to provide power to the branch again. If the reason for the excess current in the branch was transient in nature, then resetting the breaker in this manner should restore normal power to the branch. If however the branch has suffered a failure—for example, if the HVAC unit has “shorted”—the breaker 20 may once again trip, in which case the user might need to have the HVAC unit serviced before that branch is useable again.

Typically present in a circuit breaker panel 10 is a main circuit breaker 18, which intervenes between the AC power coming in from external power lines and all of the branch circuit breakers 20. The main circuit breaker 18 will trip if the sum total of the currents in the various branches exceeds the current limit for the main circuit breaker (e.g., 200 Amps), thus preventing current from flowing in any of the branches being served by the circuit breaker panel 10. Should this occur, a user can attempt to reset the main circuit breaker 18 similarly to the branch circuit breakers 20.

Construction of the circuit breaker panel 10 can vary, but as shown comprises a circuit front cover 12 through which the circuit breakers (or at least their switches) protrude. The front cover 12 is typically designed to lie flush with a wall to which it is attached via fasteners 16. The front cover 12 is removable to expose the underlying circuit breaker chassis 22 as shown in FIG. 2. The chassis 22 typically has a depth, D, and thus must be recessed into the wall if the front cover 12 is to be flush with the wall to which it is affixed. A door 14 is used to cover the circuit breaker panel 10 when access to the circuit breakers is unnecessary.

It is known in the art how to monitor the power draw at a particular home, building, or other site. For example, electrical meters have long been installed at such locations, and typically are used by electrical power companies to determine how much power has been used at the location, and thus how much the owner at that location should be charged.

The inventors have noticed that there is value in measuring the electrical power used at a location with more granularity. While it may be beneficial to know the total power drawn at a location, such as provided by a traditional electrical meter, additional benefits are provided when the power being drawn by the branches at the location is known with particularity.

This disclosure presents a solution in which a standard circuit breaker panel is fitted with hardware to wirelessly transmit information about the power being drawn by each of the branch circuit breakers in the circuit breaker panel.

### BRIEF DESCRIPTION OF THE DRAWINGS

FIG. 1 shows a circuit breaker panel of the prior art.

FIG. 2 shows a circuit breaker with its panel removed, and shows installation of an embodiment of the disclosed hub and associated wiring.

FIGS. 3A and 3B show further details of current transducers that may be used to monitor the currents in the various branch wires in the branch circuit breakers.

FIG. 4 shows the circuitry of the hub of FIG. 2.

FIGS. 5A-5D show another embodiment of hardware and circuitry for monitoring the currents in the various branch wires.

FIG. 6 shows the installation of the hub in a plurality of circuit breaker panels in a building, and shows wireless communication of the hubs with an Internet gateway.

FIG. 7A and 7B show different reports regarding circuit breaker power draws that a user can view via the Internet.

FIG. 8 shows use of an analysis module to review reported circuit breaker power draws and to provide suggestions or other useful information to a customer accordingly.

### DETAILED DESCRIPTION

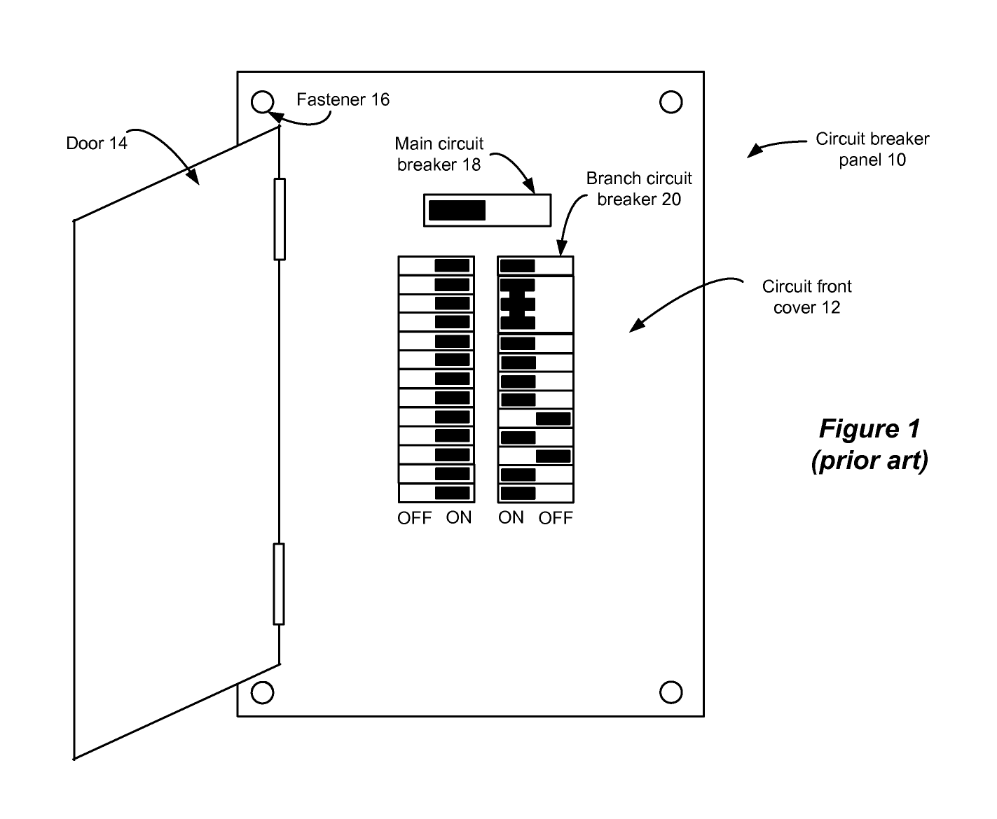

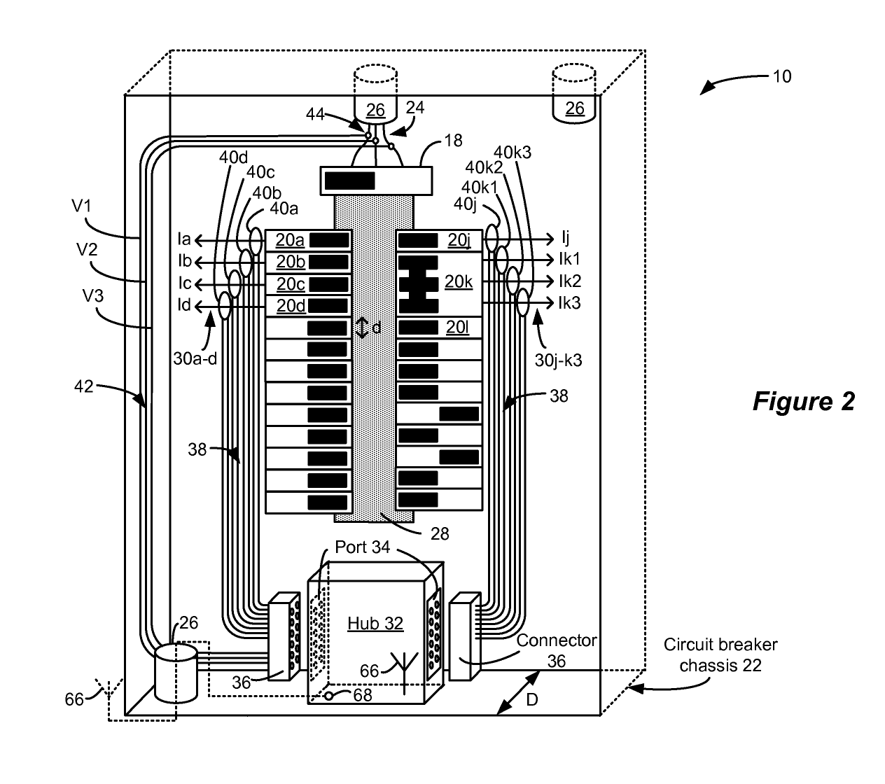

FIG. 2, as alluded to earlier, shows a circuit breaker panel 10 with its front cover 12 (FIG. 1) removed, thus exposing the underlying chassis 22. Typical structures of the chassis 22 are noticed, and are discussed first. Power is provided to the panel 10 from two or more (e.g., three) input wires 24 passing through a conduit 26 in the chassis 22. These input power wires 24 are typically coupled to external AC power lines, and may comprise, for example, single or multi-phase AC power whose line or line-to-line voltages V1, V2, and V3 (input power voltages) peak with 120-degree spacing at a frequency of 60 Hz. (A reference or neutral wire 24 may also be included, but is not shown). Other examples of input power voltages V1, V2, and V3 may comprise same phase or opposite (180-degree) phase voltages.

Input power wires 24 are input to the main circuit breaker 18 mentioned earlier, which (assuming the breaker isn't tripped) connect the input power voltages V1, V2, and V3 to a busbar array 28. Connected to the busbar array 28 are the plurality of branch circuit breakers 20 mentioned earlier. As one skilled in the art will understand, the busbar array 28 can take different shapes, and thus provide different ones of the input power voltages V1, V2, or V3 to the various branch circuit breakers 20. For example, breaker 20a may couple to V1, 20b to V2, 20c to V3, 20d to V1, and so on in alternating fashion down the array 28 as is typical. Because these breakers 20a-20d couple to only a single AC input voltage, they are known as single-phase breakers. However, other types of breakers such as multi-phase breaker 20k may also be used. For example, branch circuit breaker 20k represents a three-phase breaker, similar to the main circuit breaker 18. As such, it is coupled to all of the input power voltages V1-V3. Thus, for example, single-phase breaker 20j may connect to V1 via the busbar array 28, three-phase breaker 20k may connect to V2, V3, and V1, single-phase breaker 201 may connect to V2, again in alternating fashion. Two-phase breakers 20 could also be used, but are not shown.

Each of the branch circuit breakers 20 (again, assuming they are not tripped) connect the input power voltages to which they are connected to branch wires 30 that are ultimately routed outside of the chassis 22 though any convenient conduit 26 to the various branches at the location that they serve. Thus, and continuing the example introduced in the Background, the branch wire 30a proceeding from branch circuit breaker 20a may ultimately connect to a HVAC unit, which draws an AC current of Ia (from V1); the branch wire 30b proceeding from branch circuit breaker 20b may ultimately couple to all of the wall plugs in a kitchen, which together draw an AC current of Ib (from V2); etc. Because branch circuit breaker 20k is three-phase, it provides all three phases to some load at the location requiring all three signals, and thus draws AC currents of Ik1 (from V2); Ik2 (from V3); and Ik3 (from V1).

New to FIG. 2, and perhaps added after installation of the circuit breaker panel 10, are a wireless hub 32 and associated wiring, which will be described in further detail below. Such new equipment is fitted to the existing hardware inside the chassis 22, as facilitated by the depth D provided in the chassis, as well as space that typically exists below and to the sides of the branch circuit breakers 20. For example, notice that the wireless hub 32 is small and can sit at the bottom of the chassis 22 without interfering with a user's access to the various circuit breakers. Once the wireless hub 32 and associated wiring have been installed, the front cover 12 can be reinstalled, and the circuit breaker panel 10 will again appear as shown in FIG. 1. In short, hardware aspects of the disclosed invention are easily fit to pre-existing circuit breaker panels 10 without need for modification of those panels.

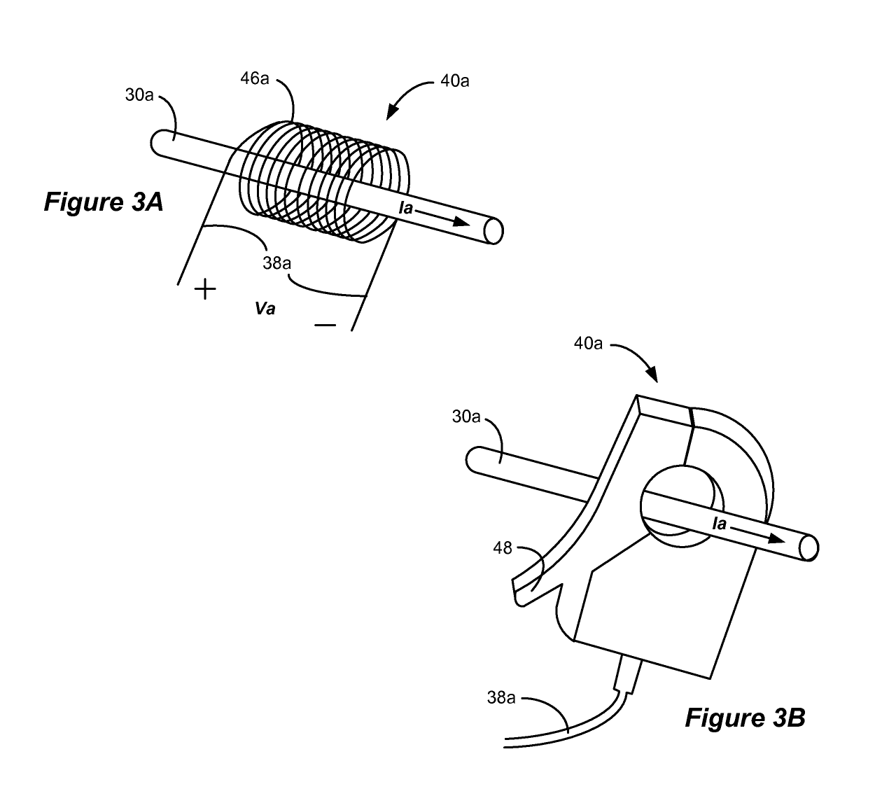

As shown, the wireless hub 32 comprises two ports 34, which couple to two connectors 36. These connectors 36 in turn are coupled to a number of current transducer (CT) output wires 38, two of which are connected to a current sensor, which is preferably a current transducer (CT) 40. Each current transducer 40 is coupled to a particular one of the branch wires 30 proceeding from each of the branch circuit breakers 20. For example, CT 40a couples to the branch wire 30a associated with branch circuit breaker 20a. As will be discussed in more detail with respect to FIG. 3, the CTs 40 provide an output relative to the branch currents (I) in each of the branch wires 30/breakers 20 to measure those currents. The relative output of the CT 40 may be a function of the branch current I. For example, the relative output may be proportional or have some other mathematical relationship such that a value indicative of the branch current I may be ascertained. One of the connectors 36 (on the left) also includes wires 42 which tap at terminals 44 to the input power wires 24 to send V1, V2, and V3 to the hub 32. The other connector 36 (on the right) can omit these input power wires 24, or they could be included and not used.

Together, a connector 36, its CT wires 38 and CTs 40, and input power taps 42 (if present) comprise a wiring harness, and thus two harnesses (left and right) are shown in FIG. 2. This is beneficial to accommodate the pre-existing layout of the circuit breaker panel 10, because the branch wires 30 generally proceed to the left and right from the left and right columns of the branch circuit breakers 20. Using left and right harnesses thus does not obscure the circuit breakers 20, and can fit in the space within the chassis 22 to the left and right of the breakers. Notice that the CTs 40 can be spaced on each harness in accordance with the spacing, d, of the branch circuit breakers 20. This facilitates connection of the CTs 40, and results in an installation in which the harness(es) fit(s) neatly inside the chassis 22 without excess slack of CT wires 38. In short, the hub 32 and wiring harnesses are designed to fit neatly inside the chassis 22, and are easily covered by the front cover 12 (FIG. 1) after installation.

However, these conveniences are not strictly necessary. The hub 32 could in other examples comprise only a single port 34 connecting with a single wiring harness (36, 38, 40, and 42), although this might make the installation more complicated and the wiring more disorganized within the chassis 22. In another alternative, multiple (e.g., two) hubs 32, each with a single port 34 and wiring harness, can be installed, for example, on the left and right sides of the chassis 22, although this is not shown for convenience.

FIGS. 3A and 3B show further details of how the CTs 40 can be coupled to the branch wires 30 proceeding from the branch circuit breakers 20 to determine their current draws. FIG. 3A shows a CT 40a (associated with branch circuit breaker 20a) having a coil 46a. The current

Ia through the branch wire 30a induces a magnetic field, which in turn induces a current in coil 46a, resulting in an output potential Va across the two CT wires 38a that feed into the hub 32. While a coil 46a will work for the CT 40a, this may require disconnecting the branch wire 30a from the circuit breaker 20a so that it can be fished through the center of the coil. FIG. 3B shows a more practical solution in which the CT 40a comprises a split core CT that can be opened via a handle 48 and clamped over the branch wire 30a. Split core CTs 40 can comprise Part No. CT232-30M (70A), CT231-30M (20A) or CT235-305 (250A), manufactured by Foashan Huaxin Metal, for instance. Because Ia is a known function of Va for a given CT (i.e., Ia=k*Va), output Va is indicative of the current Ia in breaker 20a, and hence the current flowing through that particular branch wire 30a.

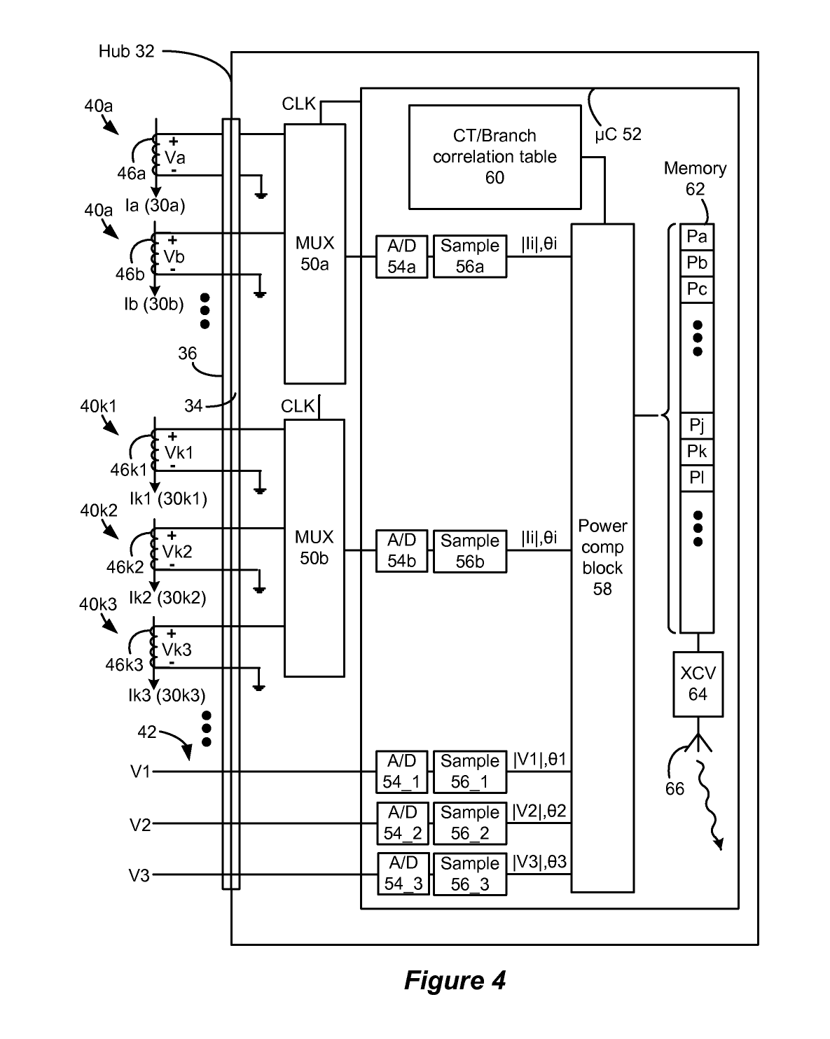

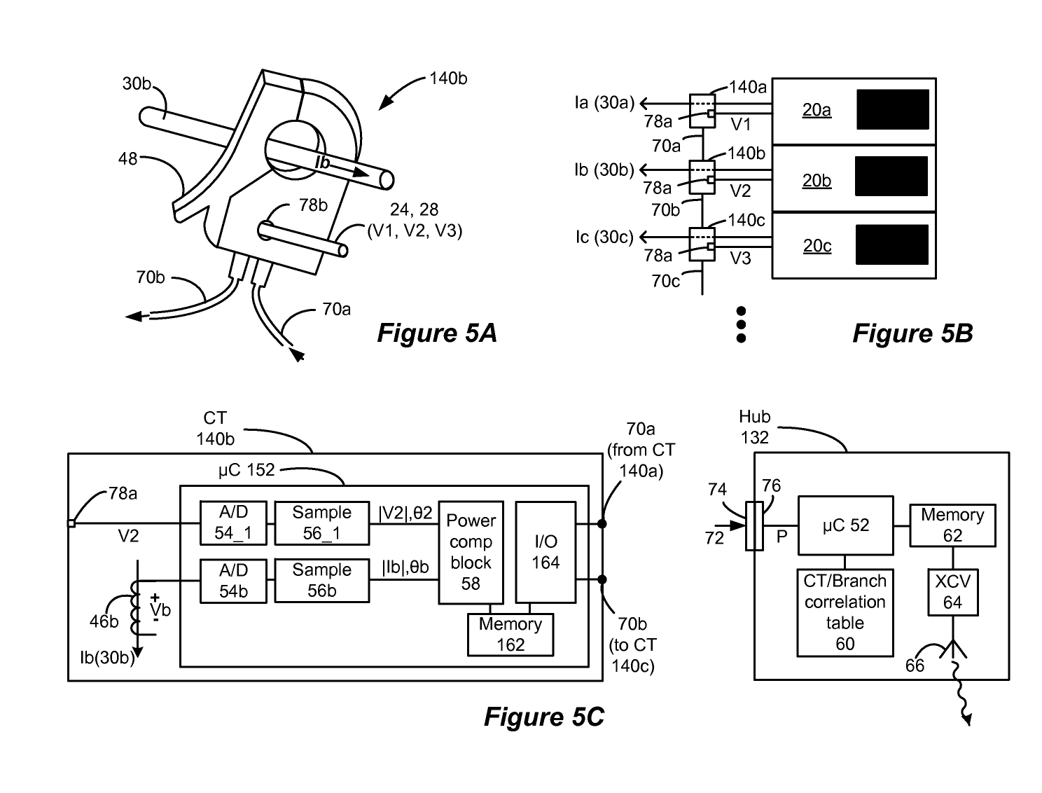

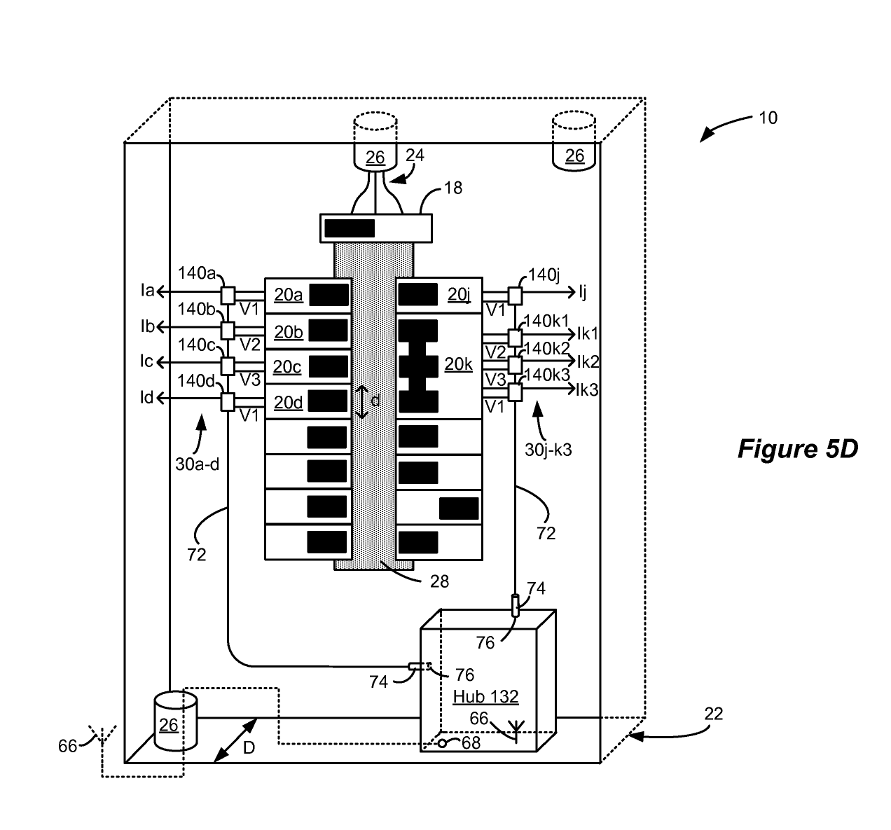

FIG. 4 shows the circuitry within the hub 32. Speaking generally, the hub 32 may receive AC voltages from each of the CTs 40, as well as the AC input power voltages V1, V2, and V3 (on input power wires 24) to determine the power being drawn by each branch serviced by the circuit breaker panel. In FIG. 4, the two connectors 36 and two ports 34 are shown as single elements for simplicity. As shown, the measured voltages Vi from CTs 40i are presented to one or more multiplexers 50. In one example, there are sixteen inputs to a given multiplexer 50, and three multiplexers 50 are used to allow for the monitoring of forty-eight different branch currents I in the circuit breaker panel 10. A microcontroller 52, such as Part No. Atmega 328P-PU, manufactured by Atmel, can provide a clock signal (CLK) to select through each of the sixteen inputs to a given multiplexer 50. In another example, branch currents (I) may be multiplexed in time as the power values described below with respect to FIGS. 5A-5D. Other types of selection schemes are also envisioned and may be provided, for example, by general purpose input/output ports (GPIO) of the microcontroller 52.

A given selected AC input Vi from a CT 40i is sampled at one or more Analog-to-Digital converter (A/D) circuit(s) 54 associated with one or more of the multiplexers 50, which may comprise one or more A/D input(s) of the microcontroller 52 as shown, or which can reside outside of the microcontroller. A/D circuit(s) 54 can produce 16-bit values indicative of the magnitude of Vi for each CT 40i. Thereafter, the digitized inputs Vi are sampled at one or more sampling circuits 56 over several cycles and scaled to determine the maximum current (|Ii|) (i.e., |Ii|=k*|Vi|) and its phase (θi) relative to a time reference. Such sampling and scaling can occur through proper programming of the microcontroller 52, which can determine and average over a number of digitized cycles of Vi where the peaks are occurring (|Vi|) and the timing of those peaks, which can in turn be converted to an angle (θi) when the input power voltage frequency (e.g., 60 Hz) is known. The input power voltages V1, V2, and V3 are likewise digitized (54_1, 54_2, 54_3) and sampled (56_1, 56_2, 56_3) to determine their maximums (|V1|, |V2|, |V3|, without scaling) and phases (θ1, θ2, and θ3).

Thereafter, the results are passed to processing circuitry such as a power computation block 58 to determine the power P being drawn by each branch. To do this, it is desirable to program the microcontroller 52 to inform which CTs 40 (and hence which input pins on the ports 34) correlate to which branches/breakers 20, as shown as table 60 in FIG. 4. This is desirable because more than one CT 40 can be used to monitor a given branch, as exemplified by the multi-phase breaker 20k introduced earlier. As discussed earlier, three-phase breaker 20k may be monitored by three CTs 40k1, 40k2, and 40k3, with the voltages provided by each (Vk1, Vk2, and Vk3) used by the power computation block 58 to determine the circuit breaker power Pk being drawn by that branch, as explained below. Thus the CT/Branch correlation table 60 would inform the power computation block 58 that voltages Vk1, Vk2, Vk3 (i.e., particular input pins of port 34 in the hub 32) comprise a single branch (corresponding to breaker 20k), and that all three voltages are to be considered when determining circuit breaker power Pk for that branch. Table 60 may also indicate which input power voltages (V1, V2, and/or V3) are being used to power a given branch/breaker 20 correspondingly being monitored.

Table 60 can be wirelessly programmed after hub 32's installation using the wireless network described subsequently, at which point the installer would take note of which branch circuit breakers 20 (and hence which input pins on the ports 34) comprise single-, double-, or three-phase breakers. Although shown as internal to the microcontroller 52, table 60 can be provided elsewhere in the hub 32.

Thereafter, the power computation block 58 can compute the circuit breaker powers P as their data are sequentially provided. For example, when the magnitude |Ia| and phase θa are reported for single-phase breaker 20a, the average power drawn by that breaker 20 (which services branch wire 30a) is computed by power computation block 58 as

Pa=1/SQRT(3)*|V1|*|Ia|*cos (θa−θ1)

with |V1| and θ1 being used because table 60 indicates that breaker 20a has been powered by V1. When the magnitudes and phases are reported for three-phase breaker 20k (servicing branch wires 30k1, 30k2, 30k3), the circuit breaker power is computed as

Pk=[1/SQRT(3)]*[|V2|*|Ik1|*cos (θk1−θ2)+|V3|*|k2|*cos (θk2−θ3)+|V1|*|Ik3|*cos (θk3−θ1)]

in accordance with connection of breaker 20k to the input power voltages as described earlier.

Measuring the input power voltages V1, V2, and V3 and applying them at the power computation block 58 is helpful in improving the accuracy of the resulting circuit breaker power measurements. For example, the magnitudes of these voltages may vary from time to time, and thus using these magnitudes in the power measurement assists in normalizing the measurements. Additionally, the power factor cos (θa-θ1) may also be computed and reported to assist in determining, among other things, branch load balancing.

Other assumptions can be made when calculating the circuit breaker powers P at the power computation block 58. For example, it may be desirable to use only one of the input power voltages V1, V2, or V3 in the power calculations, as it may be assumed that these voltages are reasonably the same at any given point in time.

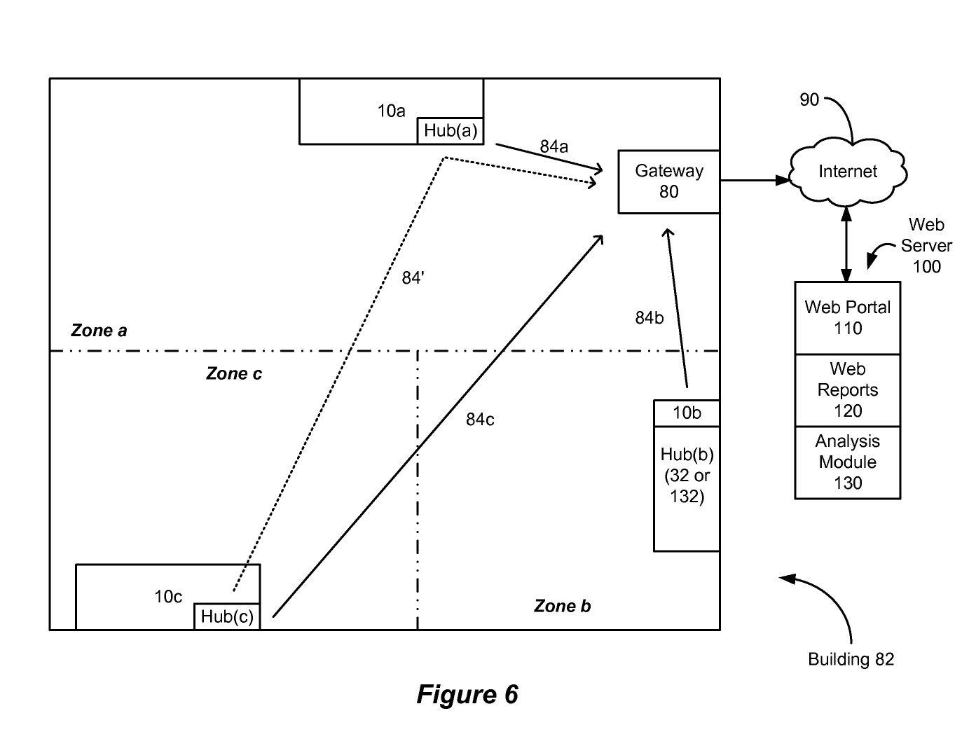

The circuit breaker powers P are sequentially stored in a memory 62, which may be internal or external to the microcontroller 52. Once all of the circuit breaker powers are determined for the circuit breaker panel 10, memory 62 provides them to a wireless transceiver 64 in the hub 32, where they are wirelessly transmitted by an antenna 66 to a wireless gateway 80 (FIG. 6), as explained in further detail later. The transceiver 64 can operate according to any number of wireless protocols, although the use of the Zigbee™ protocol is preferred. The transceiver 64 can comprise Part No. XBP24BZ7WIT-004, manufactured by Digi, for instance. The circuit breaker powers P can be telemetered from the transceiver 64 via antenna 66 every 15 to 30 seconds in one example. Optionally, the circuit breaker powers can be stored in memory 62 and telemetered with a time stamp provided by microcontroller 52 for example.

While antenna 66 is shown within the hub 32 in FIG. 4, note that the hub 32 may also include an optional port 68 allowing connection to the antenna 66, as shown in dotted lines in FIG. 2. This may allow the antenna 66 to be placed outside of the chassis 22, for example, by placing the antenna through one of the conduits 26. Such placement of the antenna 66 is advantageous because it helps prevent conductive materials of the chassis 22 from shielding, and thus interfering with, wireless communications to and from the antenna 66.

FIGS. 5A-5D show another embodiment of a system for monitoring and transmitting power drawn by the various branch wires 30/circuit breakers 20 in the breaker panel 10. In this example, and as explained further below, CTs 140 have been modified to include processing circuitry to perform some of the measurements and calculations performed by the hub 32 in earlier figures. As such, the CTs 140 can be supported by a simpler hub 132 (FIG. 5C, 5D) having less processing capability, again as explained further below.

Additionally, in this embodiment, the CTs 140 are preferably sized and spaced to fit adjacent to the circuit breaker 20, e.g., CT 140's height is less or equal to the circuit breaker spacing d. CTs 140 may also be connected serially to one another via interconnect wires 70. Thus, as shown in FIGS. 5A and 5B, each CT 140 (e.g., 140b as illustrated) includes two interconnect wires 70: an input interconnect wire 70a for receiving measurements from one or more previous CTs (140a) in the series, and an output interconnect wire 70b for reporting measurements taken and received by the CT to a subsequent CT (140c) in the series. (The first CT in the series, e.g., 140a, may not have an input interconnect wires 70a). “Daisy chained” in this way, the CTs 140 can report the circuit breaker powers P as measured at each of the CTs 140 for each of the branch wires 30 to the hub 132. This reporting can be orchestrated by the last CT 140 in the series, which can receive each of the preceding circuit breaker powers P and send them in a time-multiplexed fashion to the hub 132 via a single serialized wire 72, which wire 72 has a connector 74 connectable to a single-channel port 76 on the hub 132. As before, CTs 140 can comprise split core CTs establishing internal coils 46 for measuring the current draws in each of the branch wires 30.

Each CT 140 in this embodiment also preferably includes a contact 78 for receiving the input power voltages (V1, V2, and/or V3) that powers the particular branch wire 30/circuit breaker 20. As described below, monitoring the input power voltages at contacts 78 allows a microcontroller 152 in each CT 140 to compute circuit breaker powers with increased accuracy. As shown, it is preferred that the input power voltages be tapped at contacts 78 via a local interconnect from the busbar array 28, or from the breaker 20′s connection to the busbar 28. This is simpler and minimizes wiring bulk when compared to tapping from the input power wires 24 directly (compare FIG. 2), although such longer-distance tapping of the input power voltages is also contemplated. Tapping the busbar 28's/breaker 20's input power voltage can occur in any number of manners, and contacts 78 can for example comprise a port into which these voltages are input by a connector. Interconnect wires 70 may also interconnect the CTs 140 in any number of removable or permanent ways.

Notice that in this embodiment, and as best shown in FIG. 5D, wiring is made even more simple and compact because the left and right harnesses—i.e., CTs 140, interconnects 70, and local interconnects to contacts 78—are short, and because communication of data (circuit breaker powers) to the hub 132 are serialized. In should be understood that data, such as computed circuit breaker powers P, can be communicated in the form of data packets in a time-multiplexed fashion as already noted. Such data packets may comprise transmission of a serial string of data bits comprising a digital representation of the computed circuit breaker powers. However, such bits may also be provided in parallel, and as such, wire 72 (and interconnects 70) may comprise a parallel bus to pass the digital bits comprising the circuit breaker powers in a parallel fashion. Data packets may optionally be time-stamped to allow the hub 132 to better interpret received circuit breaker powers P, and to wirelessly transmit such powers, with benefits described subsequently. In another modification, CTs 140 may be serially connected to a common data bus (not shown) such as an I2C bus, SPI bus, RS232 bus, or the like to communicate their data packets (circuit breaker powers) to the hub 132. In yet another embodiment, hub 132 may request data packets from each CT device 140 (as stored in their memories 162) according to a schedule.

FIG. 5C shows relevant circuitry in a representative CT 140 (e.g., CT 140b) and the hub 132 in accordance with this embodiment. As shown, CT 140b includes a microcontroller 152 which, as before, digitizes (54) and samples (56) the voltage Vb across the coil 46b in the CT to determine the current draw (|Ib|) and phase (θb) in branch wire 30b/breaker 20b. The microcontroller 152 may also include a multiplexer (not shown) for selecting either on the voltages Vb or V2 as an input to a single analog-to-digital converter 54, thus eliminating the need for one of the analog-to-digital converters 54. Because breaker 20b receives input power voltage V2, that voltage is likewise digitized and sampled to determine |V2| and phase (θ2). This data allows power computation block 58 to compute the power drawn in single-phase breaker 20b (which services branch wire 30b) as follows:

Pb =1/SQRT(3)*|V2|*|Ib|*cos (θb−θ2)

which circuit breaker power Pb is stored in memory 162. Input/Output (I/O) circuitry 164 writes to and reads from memory 162 to eventually send Pb (and circuit breaker powers from other CTs 140) to the hub 132 via serialized wire 72. Thus, memory 162 can store Pb (and circuit breaker power Pa from preceding CT 140a in the serially-connected CT string) via interconnect 70a, and can provide those circuit breaker powers to a subsequent CT 140c via interconnect 70b. Although not shown, CT 140c can store these circuit breaker powers Pa and Pb in its memory 162, along with circuit breaker power Pc that it computes, and provide them to CT 140d, etc. I/O circuitry 164 can comprise well-known UART circuitry.

Eventually, all of the circuit breaker powers computed at the CTs 140 are reported to the hub 132. Because relevant measuring has occurred at the CTs, the hub 132 requires less circuitry and logic compared to the hub 32 of FIG. 4. For example, and as shown in FIG. 5C, the hub 132 can include a microcontroller 52 for receiving the circuit breaker powers P, a memory 62 for storing them, and a transceiver 64 and antenna 66 for broadcasting them (e.g., to gateway 80). (Again, antenna 66 can be placed outside of the circuit breaker chassis 22, as described earlier with respect to FIG. 2). Circuit breaker powers P can be stored and transmitted with time stamps, which may be provided by microcontrollers 152 in the CT 140, or by the microcontroller 52 in the hub 132.

Microcontroller 52 can also have access to a CT/branch correlation table 60 associating each of the circuit breakers with one or more phase powers to allow computation of a multi-phase circuit breaker's (e.g., 20 k) power (e.g., Pk). As one skilled will appreciate from the equation for a three-phase circuit breaker set forth above, such power computation (Pk) comprises adding the phase powers determined by each of the microcontrollers 152 for each of the three branch currents (Ik1, Ik2, Ik3) serviced by the three phase breaker (20 k). For a single-phase breaker, the phase power computed at the CT 140 and reported to the hub 132 will comprise the circuit breaker power, in which case processing by microcontroller 52 at the hub is not necessary.

FIG. 6 shows communication of a hub (32 or 132) with the gateway 80, and additionally shows the deployment of several hubs in several circuit breaker panels 10 within a building 82, with each circuit breaker panel 10 providing the power to a particular Zone in the building. Each of the hubs communicates via wireless links 84 to the gateway 80, which is connected to a network such as the Internet 90. The gateway 80 can comprise a ConnectPort X2e™ Programmable Zigbee IP gateway, manufactured by Digi International, Inc., for example. Use of Zigbee technology is preferred as it provides for mesh networking in which a nearest neighbor can act to repeat communications if a particular destination is too distant. Typically, the hubs can only communicate at a distance of up to 200 feet; if building 82 is large enough, some hubs (c) may be too distant to communicate directly with the gateway 80. However, communication to the gateway 80 from a distant hub (c) can occur indirectly through nearest neighbor hub (a) along path 84′, as organized automatically by the Zigbee protocol used by the hubs and the gateway 80. The gateway 80 may also comprise a memory (e.g., at least 10 GB) for buffering the circuit breaker power values. As noted earlier, the hubs may also be wirelessly programmed via the gateway 80, or through another Zigbee-compliant device such as a portable programmer.

It should be noted that because a building 82 may already have suitable gateway(s) in place, such as one or more WiFi antennas, the transceivers in the hub 32 or 132 can also be made compliant with such standards, and to transmit circuit breaker powers to such already existing devices. Therefore deployment of a separate gateway 80 in conjunction with the hubs 32 or 132 is not strictly necessary.

Once the circuit breaker powers are received at the gateway 80 for each of hubs, they can be provided to the Internet 90 and accessed via a web server 100 which might logically (but not necessarily) be under the control of the enterprise that installed the hubs in the circuit breaker panels 10. As shown, the web server 100 can provide a web portal 110 for enabling authorized users to view the reported circuit breaker powers for a particular location, or reports 120 or analysis (130) generated from some reported powers.

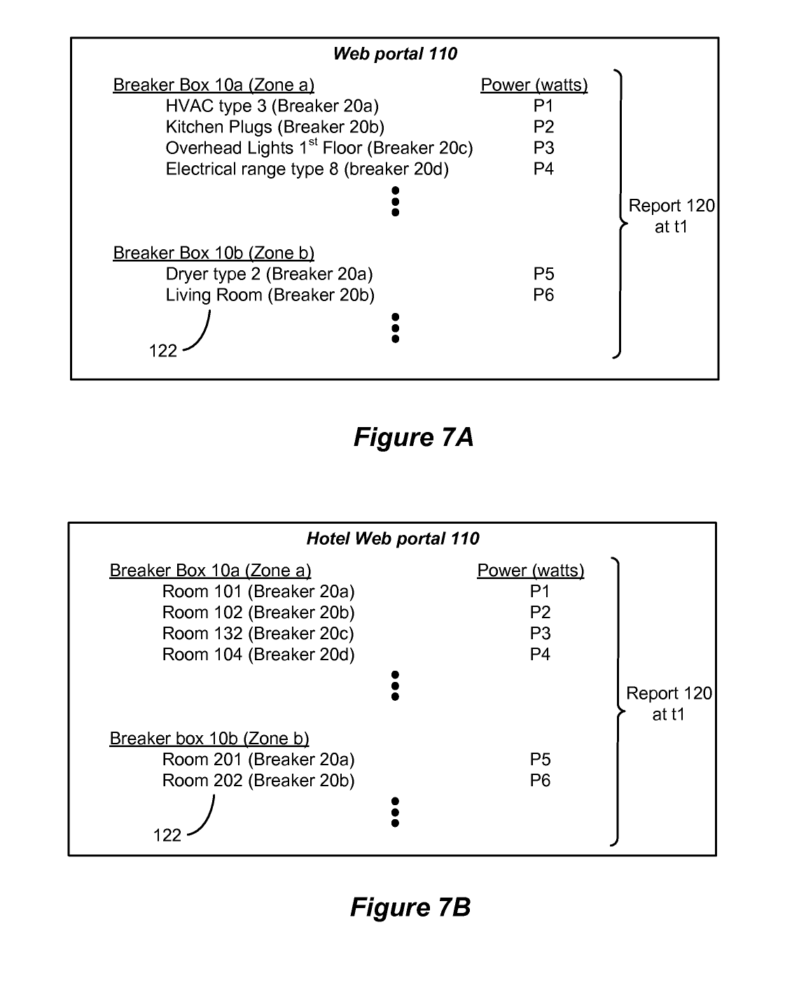

FIGS. 7A and 7B show examples of the web portal 110 as viewed on a user's internet-connected computer screen. FIG. 7A shows the example of a house, in which different branch circuit breakers services different rooms or appliances, while FIG. 7B shows the example of a hotel, in which each branch circuit breaker services a different room. Each example provides a report 120 detailing all of the circuit breaker powers reported from each of the breakers 20 in particular circuit breaker panels 10 serving particular zones in the building 82. Reports 120 can represent averages of the reported circuit breaker powers taken over a sensible time interval, such as every ten minutes for example, and older reports 120 can be saved at the web server 100 to provide a historical record of how the power might be changing on each branch in the building as a function of time.

The reports of FIGS. 7A and 7B include textual descriptions 122 of the loads or location at each branch, including possibly the type of the load present, such as HVAC type 3, which might represent a particular HVAC model sold by a particular HVAC manufacturer. Such textual descriptions 122 are helpful to the customer in understanding the reports 120. The textual descriptions 122 can be entered into a customer's record at the web server 100 by the installer once the installer has installed the invention, understands the loads at the branches, and has programmed the hub(s) and thus knows which circuit breaker powers the hub(s) will be reporting. Providing a textual description 122 of the various loads can provide useful information to an analysis module 130, which is described next. The textual descriptions 122 can also simply refer to different breaker names or positions in the circuit breaker panel 10 (20a, 20b, etc.).

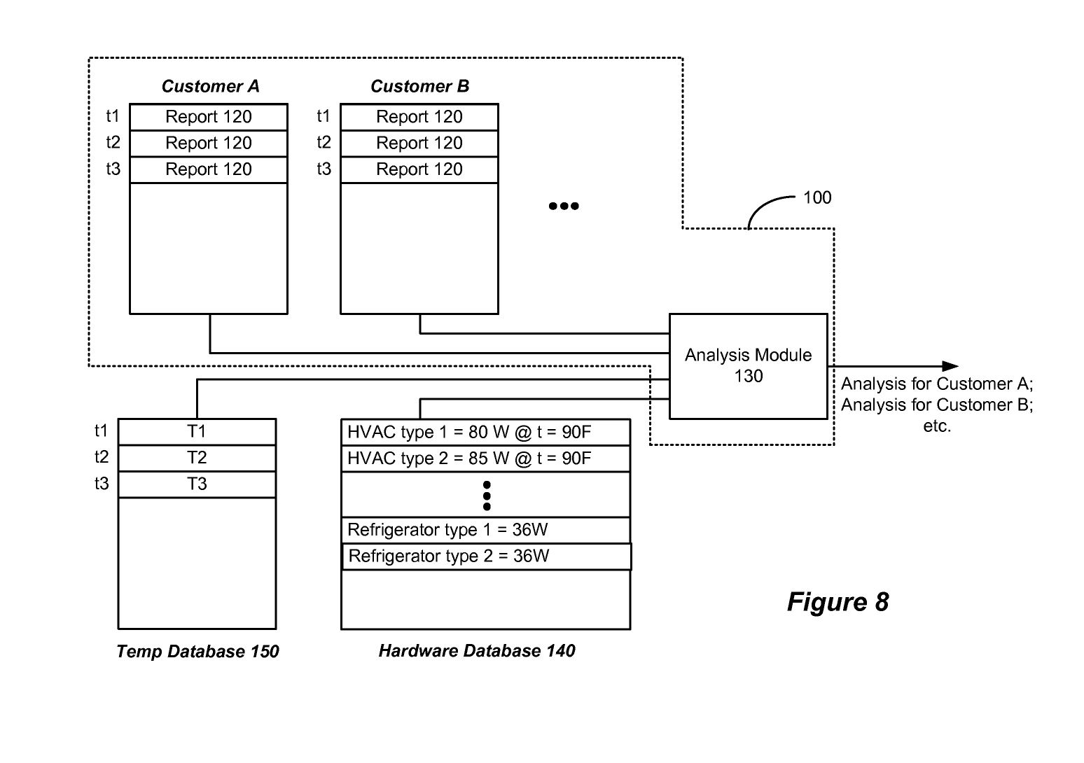

FIG. 8 shows how customer reports 120, and other helpful data, can be used by the analysis module 130 to provide useful information to a customer having the disclosed invention installed at their location. The analysis module 130 can draw from many different sources to help put the customer's power consumption in perspective. For example, the circuit breaker powers for a particular customer's report (e.g., Customer A) can be tracked as a function of time (t1, t2, t3) to understand historical trends, or to forecast future power draws. If the power on a particular branch wire 30/breaker 20 is noticed to be significantly increasing over time, the analysis module 130 may automatically notify Customer A of that fact and suggest that the customer perhaps consider servicing the equipment on that branch, which may be aging and thus drawing more power than is necessary. The analysis module 130 may also consider reported circuit breaker powers for other customers (e.g., Customer B, Customer C, etc.) when assessing the circuit breaker power draws for the customer (Customer A). For example, if Customer A has the same equipment (HVAC type 3) as other customers, the power draw for Customer A's equipment can be compared to the other customers. Again, if it is significantly higher than the average, the analysis module 130 may automatically notify Customer A of that fact to highlight a potential problem with their equipment. Similarly, the analysis module 130 can review power data from a hardware database 140, which may be accessible on the Internet 90 outside of the web server 100. The hardware database 140 can provide manufacture specifications as to the power its equipment should draw in the form of a load signature, and thus can be compared to the power draws reported for the customer. The load signature may comprise an average power magnitude and/or a power factor. If the hardware database 140 has information concerning similar but newer equipment that draws lower power, the analysis module 130 may suggest to the customer that he should consider upgrading the equipment on that branch. In short, the analysis module 130 may highlight problems, repairs, or upgrades which the customer can undertake to reduce their power consumption.

The analysis module 130 may also consider other sources having an influence on power draw. For example, a temperature database 150 can be used to correlate the timing of the reports with the outside temperature, as this information could be used to better understand power draws that are expected to vary with temperature. For example, if the analysis module 130 sees that the power draw of Customer A's HVAC unit is increasing, but also understands that the outside temperature is growing hotter from temperature data in the database 150, this might explain the power increase instead of indicating a problem.

In another example, the analysis module 130 can be used to provide discounts or incentives. In the example of a hotel (FIG. 7B), the analysis module 130 can decide which rooms have drawn lower amounts of power than average, and thus indicate which patrons in the hotel should be entitled to a discount on their bills.

A “microcontroller” as used here can comprise a single integrated circuit, or other combination of logic and memory circuits. Although shown in FIG. 4 as comprising analog-to-digital converters 54, samplers 56, a power computation block 58, memory 62, a correlation table 60, a transceiver 64, and an antenna 66, microcontroller 52 should not be considered to be so limited and may include or exclude more or less circuitry or functionality. For example, circuits that may be included in the microcontroller may include, but are not limited to: multiplexers, digital signal processors, input/output control circuitry and the like. In another example, a microcontroller may not comprise a transceiver and antenna.

Although particular embodiments of the present invention have been shown and described, it should be understood that the above discussion is not intended to limit the present invention to these embodiments. It will be obvious to those skilled in the art that various changes and modifications may be made without departing from the spirit and scope of the present invention. Thus, the present invention is intended to cover alternatives, modifications, and equivalents that may fall within the spirit and scope of the present invention as defined by the claims.

What is claimed is:

1. A system for determining a power used in each of a plurality of circuit breakers within a circuit breaker box, each circuit breaker servicing at least one branch wire and powered by at least one input power voltage, such that each circuit breaker provides at least one alternating-current branch current to its at least one serviced branch wire, the system comprising:
a plurality of current sensors each configured to measure a branch current in a branch wire within the circuit breaker box, and to provide an output indicative of the branch current in the branch wire;
a hub configurable to be positioned within the circuit breaker box, comprising:
at least one port configured to receive the outputs and the at least one input power voltage, and
a microcontroller configured to determine from the outputs and the at least one input power voltage a plurality of power values, each power value representative of the power drawn by one of the circuit breakers; and
an antenna configured to transmit the determined power values to a gateway.

2. The system of claim 1, wherein the antenna is positioned within the hub.

3. The system of claim 1, wherein the antenna is configured to couple to the hub, and wherein the antenna is configured to be positioned outside of the circuit breaker box.

4. The system of claim 1, further comprising the gateway, wherein the gateway is configured to communicate the determined power values to a server.

5. The system of claim 4, further comprising the server, the server configured to receive and analyze the plurality of power values communicated from the gateway.

6. The system of claim 5, wherein the server comprises a web portal accessible by a user and configured to display a report generated from the plurality of power values.

7. The system of claim 1, wherein the microcontroller comprises a multiplexer coupled to the port and configured to select one of the outputs.

8. The system of claim 1, wherein the microcontroller further comprises an analog-to-digital converter for producing digital samples of the outputs.

9. The system of claim 1, wherein the microcontroller is configured to determine the power value for each of the circuit breakers by assessing a magnitude and phase of the outputs of the branch wires serviced by each circuit breaker, and a magnitude and phase of the one or more input power voltages powering each circuit breaker.

10. The system of claim 1, wherein the microprocessor is configured to determine the input power voltages powering each of the circuit breakers using a table correlating each of the circuit breakers with at least one of the input power voltages.

11. The system of claim 1, wherein the outputs comprise output voltages.

12. The system of claim 11, wherein the current sensors comprise coils for producing the outputs as voltages using magnetic fields generated by the branch currents.

13. The system of claim 12, wherein the coils comprise spilt coil current transducers.

14. The system of claim 1, wherein the plurality of current sensors are coupled to a connector configured to couple to the at least one port.

15. A system for determining a power used in each of a plurality of circuit breakers within a circuit breaker box, each circuit breaker servicing at least one branch wire and powered by at least one input power voltage, such that each circuit breaker provides at least one alternating-current branch current to its at least one serviced branch wire, the system comprising:
a plurality of current sensors, each current sensor associated with a circuit breaker, each current sensor comprising:
a current transducer configured to measure a branch current in a branch wire serviced by the associated circuit breaker, and to provide an output indicative of the branch current in the branch wire, and
a first microcontroller configured to determine from the output a phase power representative of the power drawn by the branch wire,
wherein the plurality of current sensors are serially connected; and
a hub configurable to be positioned within the circuit breaker box, comprising:
at least one port configured to serially receive the phase powers from the plurality of current sensors,
a second microcontroller configured to process the plurality of phase powers if necessary to determine a plurality of power values for each circuit breaker, and
an antenna configured to transmit the power values to a gateway.

16. The system of claim 15, wherein the antenna is positioned within the hub.

17. The system of claim 15, wherein the antenna is configured to couple to the hub, and wherein the antenna is configured to be positioned outside of the circuit breaker box.

18. The system of claim 15, further comprising the gateway, wherein the gateway is configured to communicate the power values to a server.

19. The system of claim 18, further comprising the server, the server configured to receive and analyze the plurality of power values communicated from the gateway.

20. The system of claim 19, wherein the server comprises a web portal accessible by a user and configured to display a report generated from the plurality of power values.

21. The system of claim 15, wherein each first microcontroller further comprises an analog-to-digital converter for producing digital samples of the outputs.

22. The system of claim 15, wherein each first microcontroller is configured to determine the phase power by assessing a magnitude and phase of the branch current in the branch wire.

23. The system of claim 22, wherein each current sensor further comprises a contact for receiving an input power voltage powering the branch wire, and wherein each first microcontroller is configured to determine the phase power by further assessing a magnitude and phase of the input power voltage.

24. The system of claim 15, wherein second microprocessor is configured to determine the power values using a table correlating each of the circuit breakers with one or more phase powers.

25. The system of claim 15, wherein the outputs comprise output voltages.

26. The system of claim 25, wherein the current transducers comprise coils for producing the outputs as voltages using magnetic fields generated by the branch currents.

27. The system of claim 26, wherein the coils comprise spilt coil current transducers.

28. The system of claim 15 wherein the plurality of current sensors are coupled to a connector configured to couple to the at least one port.
